(19) United States
(12) Patent Application Publication
(10) Pub. No.: US 2024/0302735 A1
(43) Pub. Date: Sep. 12, 2024

(54) PELLICLE AND METHOD OF MANUFACTURING THEREOF

(71) Applicant: TAIWAN SEMICONDUCTOR MANUFACTURING COMPANY, LTD., Hsinchu (TW)

(72) Inventors: Chia-Tung KUO, Hsinchu (TW); Pei-Cheng HSU, Hsinchu (TW); Hsin-Chang LEE, Hsinchu (TW); Chin-Hsiang LIN, Hsinchu County (TW)

(21) Appl. No.: 18/118,498

(22) Filed: Mar. 7, 2023

(51) Int. Cl. G03F 1/64

(52) U.S. Cl. CPC G03F 1/64

(57) ABSTRACT

A pellicle for an extreme ultraviolet (EUV) reflective mask includes a membrane attached to a frame. The membrane includes a plurality of nanotube bundles, each including a plurality of multi-wall nanotubes made of a first nanotube material and bonded together, and a plurality wrapping layers of a second nanotube material on the plurality of nanotube bundles, the second nanotube material being different from the first nanotube material. The pellicle advantageously has good EUV light transmittance, increased strength under EUV exposure environment, and thereby prolonged lifetime.

### BACKGROUND

A pellicle is a thin transparent film stretched over a frame that is glued over one side of a photo mask to protect the photo mask from damage, dust and moisture. In extreme ultraviolet (EUV) lithography, a pellicle having high EUV light transmittance, high mechanical strength, high endurance against attacking particles, and prolonged lifetime is generally required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B and 1C show pellicles for an EUV photo mask in accordance with embodiments of the present disclosure.

FIGS. 2A, 2B, 2C and 2D show various views of multiwall nanotubes in accordance with embodiments of the present disclosure.

FIGS. 3A, 3B, 3C and 3D show structures of various membranes of a pellicle for an EUV photo mask in accordance with embodiments of the present disclosure.

FIGS. 4A and 4B show nanotube bundles of membranes including various numbers of bonded nanotubes in accordance with embodiments of the present disclosure.

FIGS. 5A, 5B and 5C show manufacturing of nanotubes and membranes in accordance with embodiments of the present disclosure.

FIGS. 6A and 6B show forming bonded bundles of nanotubes according to an embodiment of the present disclosure.

FIGS. 7A and 7B show forming wrapping layers over the bundles of nanotubes in accordance with an embodiment of the present disclosure.

FIGS. 8A, 8B and 8C show sequential operations of manufacturing a pellicle membrane for an EUV reflective mask in accordance with an embodiment of present disclosure.

FIGS. 9A and 9B are schematic views illustrating reduction of metal or metal-containing catalyst from bundles of nanotubes in accordance with an embodiment of the present disclosure.

FIG. 10A shows a flowchart of a method of making a semiconductor device, and FIGS. 10B, 10C, 10D and 10E show a sequential manufacturing operation of a method of making a semiconductor device in accordance with embodiments of present disclosure.

FIG. 11 shows a flowchart of a method of manufacturing a pellicle for an EUV reflective mask in accordance with an embodiment of present disclosure.

FIG. 12 shows a flowchart of a method of manufacturing a pellicle for an EUV reflective mask in accordance with another embodiment of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore's law. However, due to wavelength scaling from 193 nm (ArF) to 13.5 nm (even reduced to 6.7 nm), the EUV light source suffers from strong power decay due to environmental absorption. Even though a stepper/scanner chamber is operated under vacuum to prevent strong EUV absorption by gas, maintaining a high EUV transmittance from the EUV light source to a wafer is still an important factor in EUV lithography. An EUV scanner works in an environment with high hydrogen flow as well as minor nitrogen and oxygen gas flow, however a pellicle of carbon nanotubes (CNTs) is hard to withstand hydrogen/oxygen attacks.

A pellicle generally requires a high transmittance and a low reflectivity. In UV or DUV lithography, the pellicle film is made of a transparent resin film. In EUV lithography, however, a resin based film would not be acceptable, and a non-organic material, such as a polysilicon, silicide or metal film, is used.

Carbon nanotubes (CNTs) are one of the materials suitable for a pellicle for an EUV reflective photo mask, because CNTs have a high EUV transmittance of more than 96.5%. Other nanotubes made of a non-carbon based material are also usable for a pellicle for an EUV photo mask. Generally, a pellicle for an EUV reflective mask requires high EUV transmittance, strong mechanical strength, high endurance under high EUV energy exposure and hydrogen/oxygen atom attacks, and good heat dissipation to prevent the pellicle from being burnt out by EUV radiation. In some embodiments of the present disclosure, a nanotube is a one dimensional (1D) elongated nanotube having a dimeter in a range from about 0.5 nm to about 100 nm.

In the present disclosure, a pellicle for an EUV photo mask includes a frame and a membrane attached to the frame. In some embodiments, the membrane includes a plurality of nanotube bundles, each including a plurality of multi-wall nanotubes made of a first nanotube material and bonded together, and a plurality of co-axial first wrapping layers of a second nanotube material different from the first nanotube material on the plurality of nanotube bundles. In some embodiments, the membrane further includes a plurality of co-axial second wrapping layers of a third nanotube material different from the first nanotube and the second materials on the plurality of co-axial first wrapping layers. In some embodiments, the first, the second and the third materials are selected from a group consisting of C, BN, hBN, SiC, MoS₂, MoSe₂, WS₂, WSe₂, SnS₂, SnS, ZrO₂, ZrO and TiO₂. In some embodiments, an amount of any of the first, the second and the third nanotube materials is greater than 10% of a total amount thereof by weight. Such a pellicle has a high EUV transmittance, improved mechanical strength, improved endurance under high EUV energy exposure, and thus prolonged lifetime.

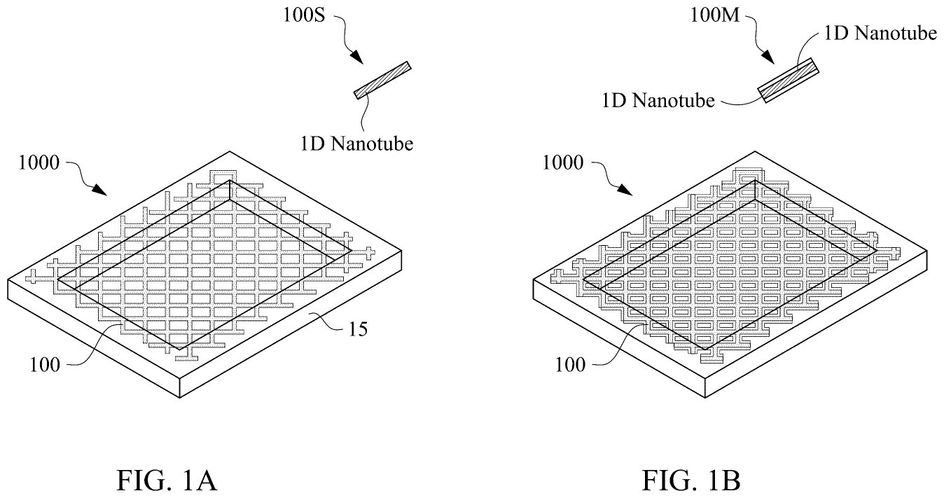

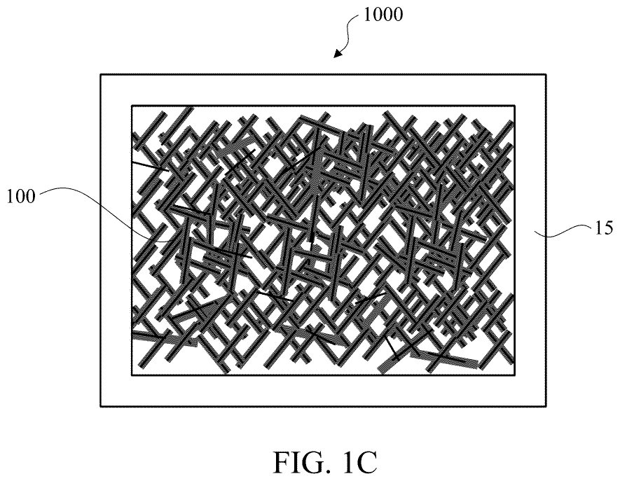

FIGS. 1A, 1B, and 1C show EUV pellicles 1000 in accordance with an embodiment of the present disclosure. In some embodiments, a pellicle 1000 for an EUV reflective mask includes a main network membrane 100 disposed over and attached to a pellicle frame 15. Terms “main network membrane”, “pellicle membrane”, and “membrane” are interchangeably used here. In some embodiments, a membrane is attached to a border formed of e.g., Si, Qz or other materials, and is attached to a frame with vent holes, not shown. In some embodiments, the main network membrane 100 are formed by a plurality of single-wall or multiwall nanotubes made of a single material, and in other embodiments, the main network membrane 100 are formed by a plurality of single-wall or multiwall nanotubes made of different materials. In some embodiments, the single-wall or multiwall nanotube bundles are dispersed in a specific orientation as shown in FIGS. 1A and 1B. In other embodiments, the single-wall or multiwall nanotube bundles are randomly dispersed as shown in FIG. 1C. In some embodiments, a nanotube is a one dimensional (1D) elongated nanotube having a dimeter in a range from about 0.5 nm to about 100 nm, and in other embodiments, the dimeter of the 1D elongated nanotube is in a range from about 10 nm to about 1000 um.

In some embodiments, as shown in FIG. 1A, the main network membrane 100 includes a plurality of single-wall nanotubes 100S. In some embodiments, as shown in FIG. 1A, the main network membrane 100 includes a plurality of multi-wall nanotubes 100S. In some embodiments, the single-wall nanotubes are carbon nanotubes, and in other embodiments, the single-wall nanotubes are nanotubes made of a non-carbon based material. In some embodiments, the multi-wall nanotubes are carbon nanotubes, and in other embodiments, the multi-wall nanotubes are nanotubes made of a non-carbon based material.

In other embodiments, as shown in FIG. 1B, the main network membrane 100 includes a plurality of multiwall nanotubes 100M. In some embodiments, a multiwall nanotube is a co-axial nanotube having two or more tubes co-axially surrounding at least one inner tube. In some embodiments, the main network membrane 100 includes only one type of nanotubes and in other embodiments, different types of nanotubes form the main network membrane 100.

In some embodiments, a pellicle frame 15 is attached to the main network membrane 100 to maintain a space between the main network membrane 100 of the pellicle 1000 and a pattern of an EUV mask (not shown) when mounted on the EUV mask. In some embodiments, a membrane (e.g., formed of multi-wall CNTs) is attached to a border (e.g., formed of Si, Qz, or other materials), and is attached to a frame (e.g., formed of Ti or other materials) with vent holes, not shown. The pellicle frame 15 of the pellicle 1000 is attached to the surface of the EUV photo mask with an appropriate bonding material. In some embodiments, the bonding material is an adhesive, such as an acrylic or silicon based glue or an A-B cross link type glue. The size of the frame structure is larger than the area of the black borders of the EUV photo mask so that the pellicle covers not only the pattern area of the photo mask but also the black borders.

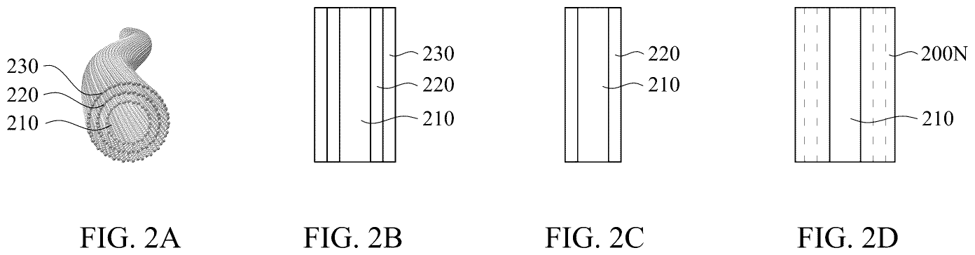

FIGS. 2A, 2B, 2C and 2D show various views of multiwall nanotubes in accordance with embodiments of the present disclosure. In some embodiments, the nanotubes in the main network membrane 100 as shown in FIG. 1B include single-wall carbon nanotubes 100S, and in other embodiments, the nanotubes in the main network membrane 100 include multiwall nanotubes 100M, which are also referred to as co-axial nanotubes 100M. In some embodiments, a multi-wall carbon nanotube 100M includes a number of walls in a range from 2 to 10.

FIG. 2A shows a perspective view of a multiwall co-axial nanotube 100M having threes tubes 210, 220 and 230, and FIG. 2B shows a cross sectional view thereof. In some embodiments, the inner tube (or innermost tube) 210 is a carbon nanotube, and two outer tubes 220 and 230 are non-carbon based nanotubes, such as boron nitride nanotubes. In some embodiments, all tubes are non-carbon based nanotubes.

The number of tubes of the multiwall nanotubes is not limited to three. In some embodiments, the multiwall nanotube has two co-axial nanotubes as shown in FIG. 2C. In other embodiments, the multiwall nanotube includes the innermost tube 210 and the first to N-th nanotubes including the outermost tube 200N, where N is a natural number from 1 to about 20, as shown in FIG. 2D. In some embodiments, N is up to 10 or up to 5. In some embodiments, at least one of the first to the N-th outer layers is a nanotube coaxially surrounding the innermost nanotube 210. In some embodiments, two of the innermost nanotubes 210 and the first to the N-th outer layers 220, 230, . . . 200N are made of different materials from each other. In some embodiments, N is at least two (i.e., three or more tubes), and two of the innermost nanotubes 210 and the first to the N-th outer tubes 220, 230, . . . 200N are made of the same materials. In other embodiments, three of the innermost nanotubes 210 and the first to the N-th outer tubes 220, 230, . . . 200N are made of different materials from each other.

In some embodiments, at least two of the tubes of the multiwall nanotube are made of a different material from each other. In some embodiments, adjacent two layers (tubes) of the multiwall nanotube are made of a different material from each other. In some embodiments, an outermost nanotube of the multiwall nanotube is a non-carbon based nanotube. In some embodiments, the outermost tube or outermost layer of the multiwall nanotubes is made of at least one layer of BN.

In some embodiments, the multiwall nanotube includes three co-axially layered tubes made of different materials from each other. In other embodiments, the multiwall nanotube includes three co-axially layered tubes, in which the innermost tube (first tube) and the second tube surrounding the innermost tube are made of materials different from each other, and the third tube surrounding the second tube is made of the same material as or different material from the innermost tube or the second tube.

In some embodiments, a diameter of the innermost nanotube is in a range from about 0.5 nm to about 20 nm and is in a range from about 1 nm to about 10 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 μm to about 50 μm and is in a range from about 1.0 μm to about 20 μm in other embodiments.

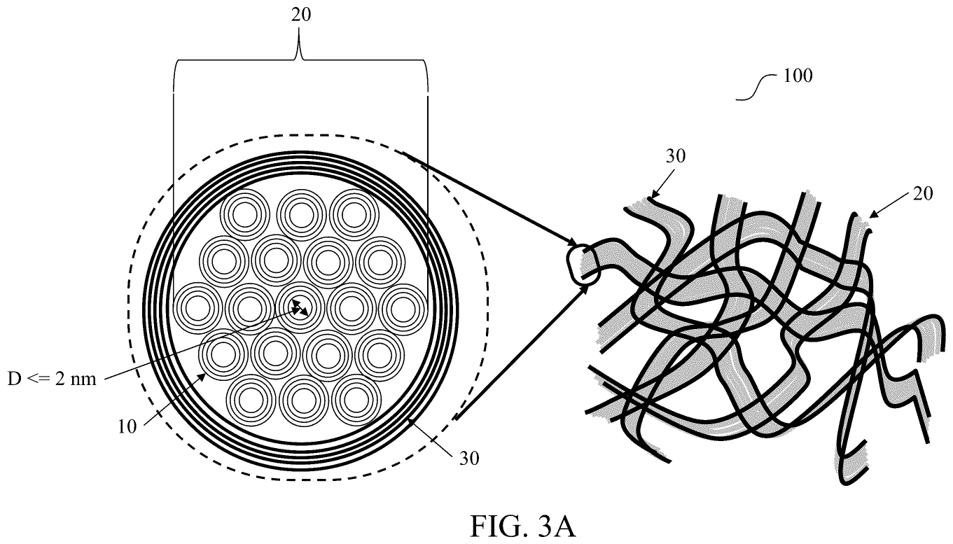

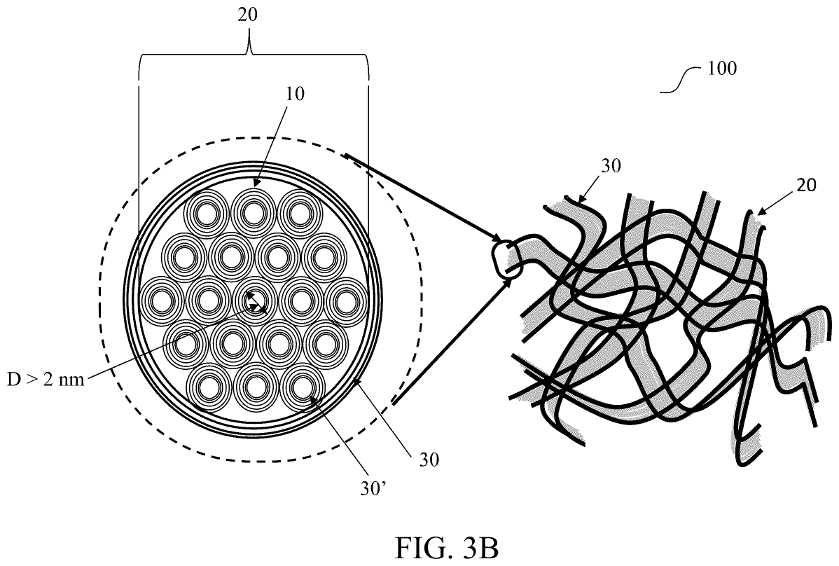

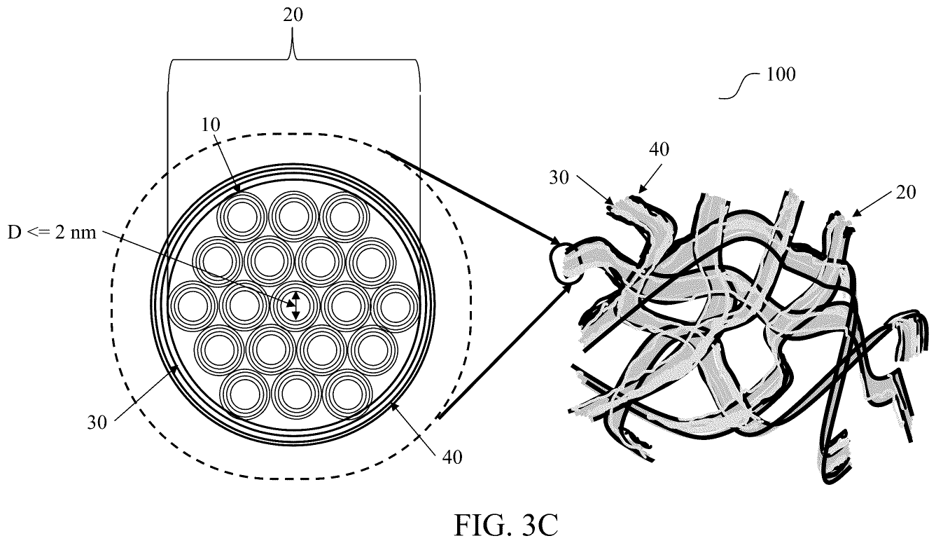

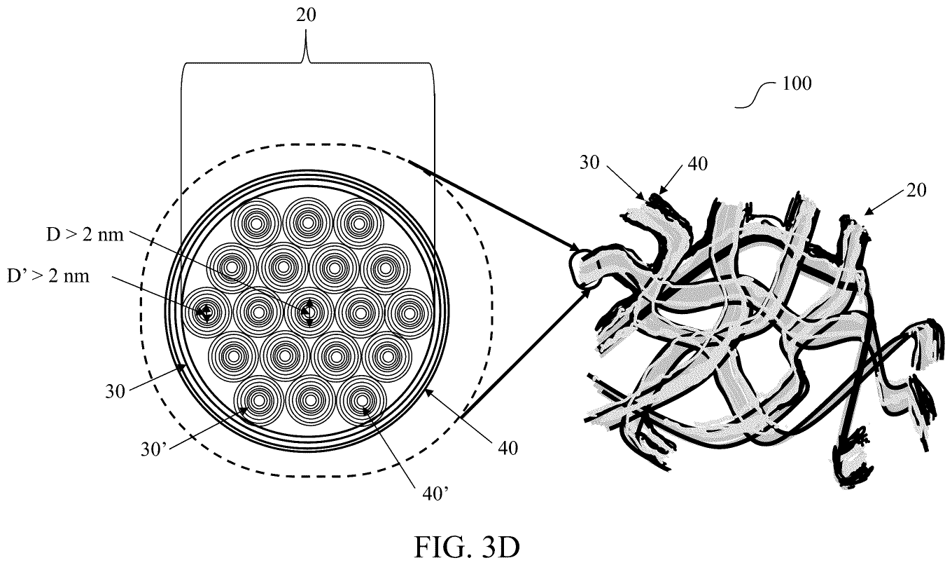

FIGS. 3A, 3B, 3C and 3D show structures of various membranes 100 of a pellicle for an EUV photo mask in accordance with embodiments of the present disclosure. In some embodiments, a pellicle for an EUV reflective mask includes a frame 15 and a membrane 100 attached to the frame 15 as shown in FIG. 1A or FIG. 1B.

As shown in FIGS. 3A and 3B, in some embodiments, the membrane 100 includes a plurality of nanotube bundles 20, each nanotube bundle 20 including a plurality of single-wall or multiwall nanotubes 10 made of a first material and bonded together. The membrane 100 further includes a plurality of co-axial wrapping layers 30 of a second material, different from the first material, surrounding the plurality of nanotube bundles 20.

In some embodiments, as shown in FIG. 3A, when the inner diameter D of the plurality of multi-wall nanotubes 10 is equal to or less than 2 nm (D≤2 nm), the plurality of nanotubes 10 do not include any layers 30′ of the second material filled within inner-most walls of the plurality of nanotubes 10. In other words, each of the plurality of nanotubes 10 is made of the same (single) material.

In other embodiments, as shown in FIG. 3B, when the inner (or innermost) diameter D of the plurality of multi-wall nanotubes 10 is greater than 2 nm (D>2 nm), the plurality of nanotubes 10 of the first material further includes one or more layers 30′ of the second material filled within inner-most walls of the plurality of nanotubes 10.

As shown in FIGS. 3A and 3B, in some embodiments, the first material used to form nanotubes 10 includes a carbon-based nanotube (CNT) material, and the second nanotube material used to form co-axial wrapping layers 30 includes BN nanotube (BNNT) material. In some embodiments, the first material used to form the nanotubes 10 includes a carbon based material, and the second material used to form the co-axial wrapping layers 30 includes non-carbon based materials, such as BN, hBN, SiC, MoS₂, MoSe₂, WS₂, WSe₂, SnS₂, SnS, ZrO₂, ZrO or TiO₂. In some embodiments, the first material used to form the nanotubes 10 and the second material used to form the co-axial wrapping layers 30, different from each other, are respectively selected from C, BN, hBN, SiC, MoS₂, MoSe₂, WS₂, WSe₂, SnS₂, SnS, ZrO₂, ZrO or TiO₂. In some embodiments, an amount of any of the first material used to form the nanotubes 10 and the second material used to form the co-axial wrapping layers 30 is greater than 10% of a total amount thereof by weight, and in other embodiments, the amount of any of the first material and the second material is greater than 15% of the total amount thereof by weight.

As shown in FIGS. 3C and 3D, in other embodiments, the membrane 100 includes a plurality of nanotube bundles 20, each including a plurality of multi-wall nanotubes 10 made of a first material and bonded together, a plurality of co-axial first wrapping layers 30 of a second material surrounding the plurality of nanotube bundles 20, and a plurality of co-axial second wrapping layers 40 of a third material surrounding on the plurality of co-axial first wrapping layers 30. The first material used to form the nanotubes 10, the second material used to form the co-axial first wrapping layers 30, and the third material used to form the co-axial second wrapping layers 40 are different from each other.

As shown in FIGS. 3C and 3D, in some embodiments, the first material used to form the nanotubes 10 includes a carbon-based nanotube (CNT) material, the second nanotube material used to form the co-axial first wrapping layers 30 is selected from a group consisting of SiC, MoS₂, MoSe₂, WS₂, WSe₂, SnS₂, SnS, ZrO₂, ZrO and TiO₂, and the third material used to form the co-axial second wrapping layers 40 is BN. In some embodiments, the first, the second, and the third nanotube materials are different from each other and are respectively selected from a group consisting of C, BN, hBN, SiC, MoS₂, MoSe₂, WS₂, WSe₂, SnS₂, SnS, ZrO₂, ZrO and TiO₂. In some embodiments, an amount of any of the first material used to form the nanotubes 10, the second material used to form the co-axial first wrapping layers 30, and the third material used to form the co-axial second wrapping layers 40 is greater than 10% of a total amount thereof by weight.

In some embodiments, as shown in FIG. 3C, when the inner (or innermost) diameter D of the plurality of multiwall nanotubes 10 is equal to or less than 2 nm (D≤2 nm), the plurality of nanotubes 10 do not include any layers 30′ of the second nanotube material or any layers 40′ of the third nanotube material filled within innermost walls of the plurality of nanotubes 10.

In other embodiments, as shown in FIG. 3D, when the inner (or innermost) diameter D of the plurality of multiwall nanotubes 10 is greater than 2 nm (D>2 nm), the plurality of nanotubes 10 of the first material includes one or more layers 30′ of the second nanotube material filled within inner-most walls of the plurality of nanotubes 10. Furthermore, when the inner (or innermost) inner diameters D′ of the one or more layers 30′ of the second nanotube material within innermost walls of the plurality of multi-wall nanotubes 10 of the first material are greater than 2 nm, the plurality of nanotubes 10 of the first material includes one or more layers 40′ of the third nanotube material within innermost walls of the one or more layers 30′ of the second nanotube material.

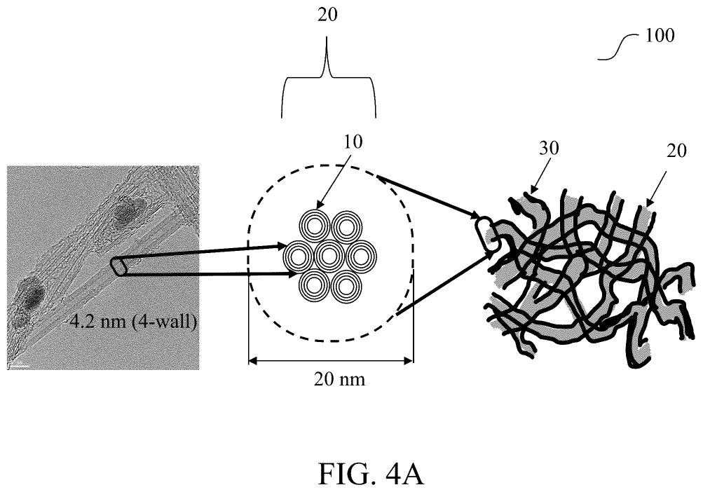

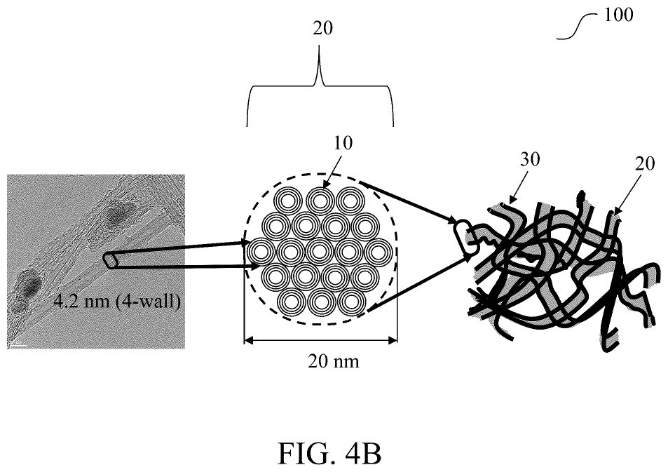

FIGS. 4A and 4B show nanotube bundles 20 of membranes 100 including various numbers of bonded nanotubes in accordance with embodiments of the present disclosure. As shown in FIG. 4A, a bundle 20 includes 7 bonded nanotubes 10 and is classified as a medium bundle, which is defined as including 2-15 bonded nanotubes per nanotube bundle. As shown in FIG. 4B, a bundle 20 includes 19 bonded nanotubes 10 and is classified as a large bundle, which is defined as including 16-100 bonded nanotubes 10 per bundle. A bundle 20 including more than 100 bonded nanotubes 10 is defined as a very large bundle (not shown in the figures).

The membrane 100, as shown in FIG. 4B, formed of nanotube bundles 20 each including 19 nanotubes is stronger than the membrane 100, as shown in FIG. 4A, formed of nanotube bundles 20 each including 7 nanotubes. However, the EUV transmittance of the membrane 100 as shown in FIG. 4B is lower than the EUV transmittance of the membrane 100 as shown in FIG. 4A. In some embodiments, a transmittance of the membrane 100 is in a range from about 50% to about 99%, and in other embodiments, the transmittance of the membrane 100 is in a range from about 60% to about 90%. In some embodiments, the membrane 100 includes either one of or both of the medium bundles and/or the large bundles. It is noted that the configurations and/or structures as explained with FIGS. 4A and 4B above can be applied to any one of the membranes as explained with FIGS. 3A-3D.

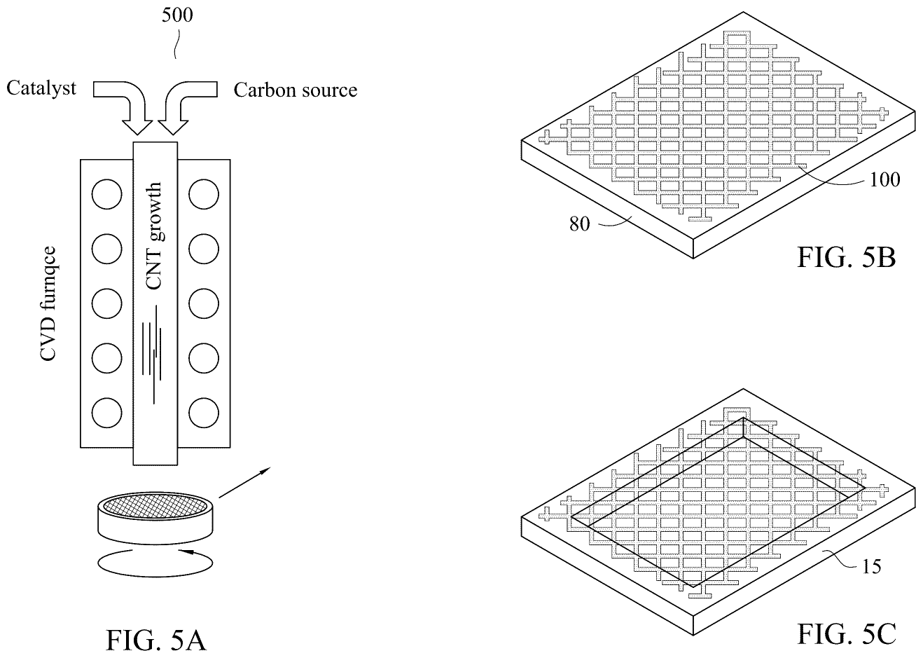

FIGS. 5A, 5B and 5C show manufacturing of nanotubes 10 and membranes 100 in accordance with embodiments of the present disclosure. Nanotubes 10 and membranes 100 are not limited to be formed only in this way, and can be formed in other ways.

In some embodiments, nanotubes 10 are formed by a chemical vapor deposition (CVD) process. In some embodiments, the CVD process is performed by using a vertical furnace 500 as shown in FIG. 5A, and synthesized nanotubes are deposited on a support membrane 80 as shown in FIG. 5B. In some embodiments, carbon-based nanotubes are formed from a carbon source gas (precursor) using an appropriate catalyst, which is selected from a group consisting of Fe, CoFe, Co, CoNi, Ni, CoMo, and FeMo. In other embodiments, non-carbon based nanotubes are formed from a non-carbon source gas, which is a precursor containing B, S, Se, Mo and/or W, and using an appropriate catalyst, which is selected from a group consisting of Fe, CoFe, Co, CoNi, Ni, CoMo, and FeMo. Then, the membrane 100 formed over a support membrane 80 is detached from the support membrane (or filter) 80, and transferred on to the pellicle frame 15 as shown in FIG. 5C. In some embodiments, a stage or a susceptor, on which the support membrane 80 is disposed, rotates continuously or intermittently (step-by-step manner) so that the synthesized nanotubes are deposited on the support membrane 80 with different or random directions.

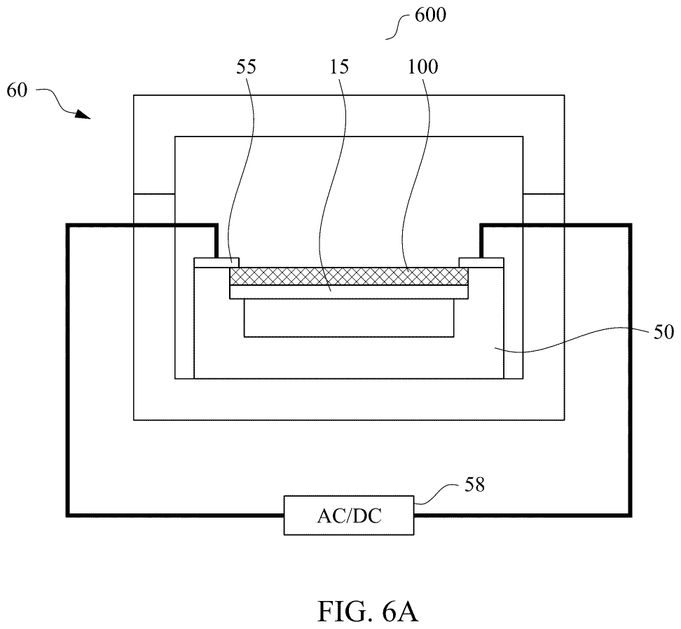

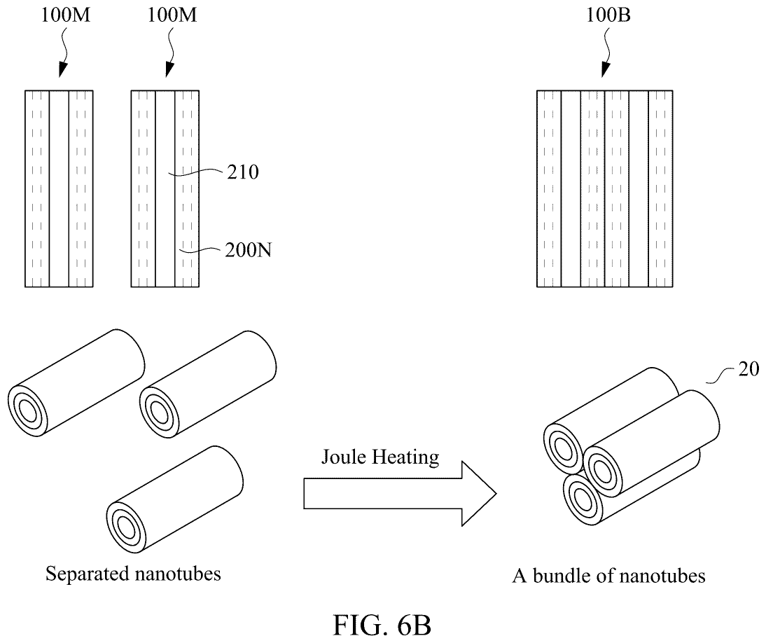

FIGS. 6A and 6B show forming bonded bundles 20 of nanotubes 10 of a membrane 100 (as shown in FIG. 3A, 3B, 3C or 3D) according to an embodiment of the present disclosure. Bundles 20 of nanotubes 10 of a membrane 100 are not limited to be formed only in the ways as shown in FIGS. 6A and 6B, and can be formed in other ways.

As shown in FIG. 6A, a membrane 100 and a frame 15 of a pellicle 1000 (as shown in FIGS. 1A and 1B) is placed over an insulating support 50 and is clamped at the edge portions of the pellicle by parts of the insulating support 50 and electrodes 55. The insulating support 50 is made of ceramic in some embodiments, and the electrodes 55 are made of metal, such as tungsten, copper or steel. The electrodes 55 are attached to contact the membrane 100. In some embodiments, the electrodes 55 are attached to two side portions (e.g., left and right) of the membrane 100. In some embodiments, the length of the electrodes are greater than the length of the sides of the membrane 100 and the frame 15. In some embodiments, the membrane 100 and the frame 15 are horizontally supported. In some embodiments, the electrodes 55 are connected to a current source (power supply) 58 by wires.

As shown in FIG. 6A, a Joule heating apparatus 600 on which a membrane 100 formed of one or more nanotube materials is mounted is placed in a vacuum chamber 60. In some embodiments, the vacuum chamber 60 includes a bottom part in which the Joule heating apparatus is placed and an upper (lid) part, and a gasket (e.g., O-ring) is disposed between the bottom part and the upper part. The wires of the Joule heating apparatus are connected to outside wires, which are connected to the power supply 58.

In the Joule heating operation, the vacuum chamber is evacuated to a pressure equal to or lower than 10 Pa in some embodiments. In some embodiments, the pressure is more than 0.1 Pa. The power supply 58 applies current to the membrane 100 so that the current passes through the membrane generating heat. In some embodiments, the current is DC, and in other embodiments, the current is AC or pulse current.

In some embodiments, the current from the power supply 58 is adjusted such that the membrane is heated at a temperature in a range from about 800° C. to 2000° C. In some embodiments, the lower limit of the temperature is about 1000° C., 1200° C. or 1500° C., and the upper limit is about 1500° C., 1600° C. or 1800° C. In some embodiments, the temperature can be adjusted so that metal particles (e.g., iron as residual catalyst) is vaporized under the vacuum and evacuated. In this way, the catalyst, for example, selected from a group consisting of Fe, CoFe, Co, CoNi, Ni, CoMo, and FeMo and used when forming the membrane 100 made of the nanotubes 10, is greatly reduced from the membrane 100 due to the high temperature adopted during the process of forming bundles 20 of nanotubes, thereby advantageously improving transmittance of the membrane 100.

When the temperature is lower than these ranges, the contaminant may not be fully removed, and when the temperature is higher than these ranges, the membrane and/or frame may be damaged. In some embodiments, the pellicle frame 15 is made of ceramic or a metal or metallic material having a higher electric resistance than the carbon nanotube membrane 100.

In some embodiments, the Joule heating treatment is performed in an inert gas ambient, such as N₂ and/or Ar. In some embodiments, the Joule heating treatment is performed for about five seconds to about 60 minutes, and is performed to about 30 seconds to about 15 minutes in other embodiments. When the heating time is shorter than these ranges, the contaminant may not be fully removed, and when the heating time is longer than these ranges, a cycle time or a process efficiency may be degraded.

As shown in FIG. 6B, in some embodiments, the Joule heating operation causes single separated nanotubes (single-wall or multiwall nanotubes) to join and form a bundle 20 of nanotubes 10 having a seamless graphitic structure, in which the nanotubes are firmly bonded or joined more than merely contacting each other. Two or more nanotubes 10 can be connected (bonded or joined) to form a bundle 20 of nanotubes 10. In some embodiments, 2-15 nanotubes 10 are bonded to form a medium bundle 20. In some embodiments, 16-100 nanotubes 10 are bonded to form a large bundle 20. In some embodiments, more than 100 nanotubes 10 are bonded to form a very large bundle 20.

In some embodiments, the carbon nanotube (CNT) membrane 100 as formed before the Joule heating treatment includes no or a small number of bundles of nanotubes, and after the Joule heating treatment, the number of the bundles of carbon nanotubes increases.

In other embodiments, in another way of forming CNT bundles, after a CNT membrane is already formed, the CNT membrane is dipped in a solvent (such as isoamyl acetate) with a high boiling point, and then is washed and dried, so that CNTs of the membrane contact and bond each other during the solvent vaporing, thereby forming CNT bundles.

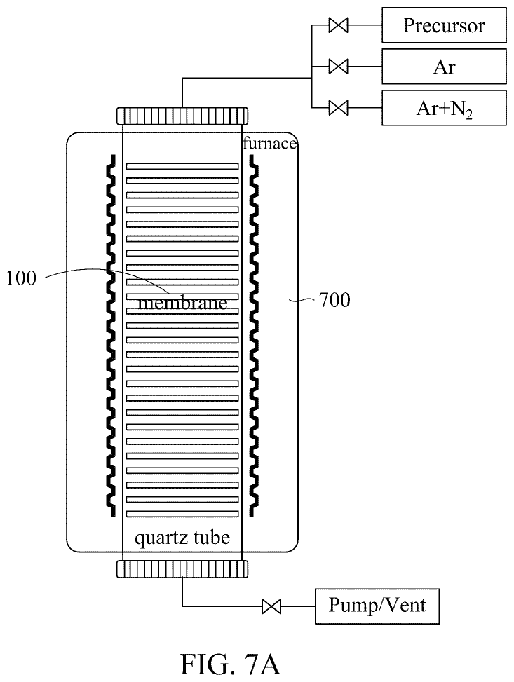

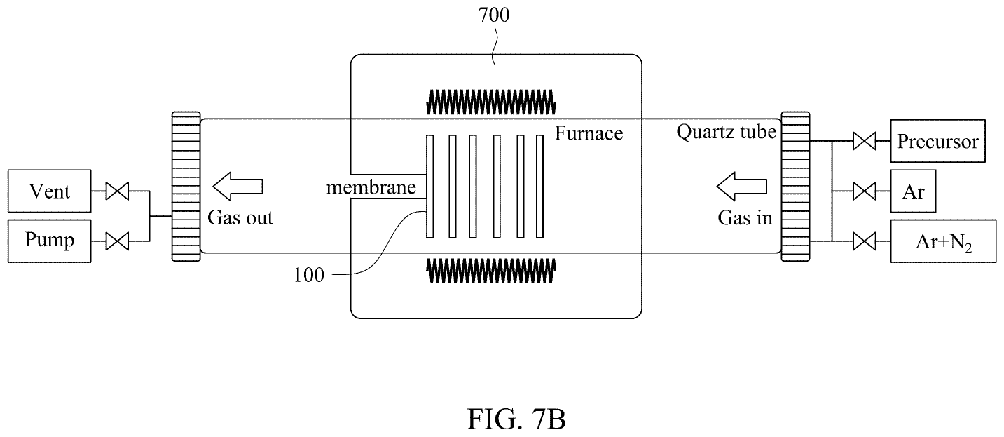

FIG. 7A shows forming the wrapping layers 30 of a second material over bundles 20 of nanotubes 10 of a first material that forms pellicle membranes 100 (e.g., as shown in FIGS. 3A and 3B) using a vertical furnace 700 in accordance with some embodiments of the present disclosure, in which the pellicle membranes 100 including a plurality of nanotube bundles are horizontally placed in the vertical furnace 700 as shown in FIG. 7A.

FIG. 7B shows forming the wrapping layers 30 of a second material over the bundles 20 of nanotubes 10 of a first material that forms membranes 100 (e.g., as shown in FIGS. 3A and 3B) using a horizontal furnace 700 in accordance with other embodiments of the present disclosure, in which the membranes 100 including a plurality of nanotube bundles are vertically placed in the horizontal furnace 700 as shown in FIG. 7B.

In some embodiments, the first material includes C, and the second material includes BN. In some embodiments, the first material and the second material are different and are respectively selected from a group consisting of C, BN, hBN, SiC, MoS₂, MoSe₂, WS₂, WSe₂, SnS₂, SnS, ZrO₂, ZrO and TiO₂.

In some embodiments, the working temperature in the furnace 700 is in a range from about 500° C. to about 600° C. In some embodiments, the working temperature in the furnace 700 is in a range from about 900° C. to about 1000° C. In some embodiments, the working temperature in the furnace 700 is in a range from about 1000° C. to about 1100° C.

As shown in FIG. 3B, in some embodiments, due to the high working temperature in the furnace 700, when the inner diameter D of the plurality of multi-wall nanotubes 10 of the first material (such as C) is greater than 2 nm (D>2 nm), one or more layers 30′ of the second material (such as BN) fill into innermost walls of the plurality of nanotubes 10.

As shown in FIG. 3D, in some embodiments, due to the high working temperature in the furnace 700, when the inner diameter D of the plurality of multi-wall nanotubes 10 of the first material (such as C) is greater than 2 nm (D>2 nm), one or more layers 30′ of the second nanotube material (such as SiC) fill into innermost walls of the plurality of nanotubes 10. Furthermore, as shown in FIG. 3C, due to the high working temperature in the furnace 700, when the inner diameters D′ of the one or more layers 30′ of the second nanotube material are greater than 2 nm (D′>2 nm), one or more layers 40′ of the third nanotube material (such as BN) fill into innermost walls of the one or more layers 30′ of the second nanotube material within the plurality of nanotubes 10.

In some embodiments, H₃BO₃ is used as a B precursor, N₂ is used as N precursor, Ar gas is used as a carrier gas, and Ar gas is also used as a purge gas to deposit wrapping layers 30 of a second material (such as BN) over the bundles 20 of nanotubes 10 of a first material that forms membranes 100 (as shown in FIGS. 3A and 3B) for about 60 minutes. In some embodiments, the working temperature is in range from about 800° C. to about 1200° C., and is in range from about 900° C. to about 1100° C. in other embodiments. In some embodiments, the working pressure is in range from about 0.8 atm to about 1.2 atm, and is in range from about 0.9 atm to about 1.1 atm in other embodiments.

In some embodiments, BO₃ is used as a B precursor, NH₃ is used as N precursor, Ar gas is used as a carrier gas (with a ration of NH₃ and Ar of 1:4), and Ar gas is used as a purge gas to deposit wrapping layers 30 of a second material (such as BN) over the bundles 20 of nanotubes 10 of a first material that forms pellicle membranes 100 (as shown in FIGS. 3A and 3B) for about 60 minutes. In some embodiments, the working temperature is in range from about 1000° C. to about 1400° C., and is in range from about 1100° C. to about 1300° C. in other embodiments. In some embodiments, the working pressure is in range from about 0.8 atm to about 1.2 atm, and is in range from about 0.9 atm to about 1.1 atm in other embodiments.

In some embodiments, H₃BO₃ is used as a B precursor, NH₃ is used as N precursor at a flow rate of about 50 standard cubic centimeter per minute (sccm), and Ar gas is used as a purge gas to deposit wrapping layers 30 of a second material (such as BN) over the bundles 20 of nanotubes 10 of a first material that forms membranes 100 (as shown in FIGS. 3A and 3B) for about 60 minutes. In some embodiments, the working temperature is in range from about 800° C. to about 1000° C. In some embodiments, the working pressure is in range from about 0.9 atm to about 1.1 atm.

In some embodiments, NaBH₄ (typically in powder form) is sublimed and used as a B precursor, NH₄Cl is used as N precursor, and Ar gas is used as a purge gas to deposit wrapping layers 30 of a second material (such as BN) over the bundles 20 of nanotubes 10 of a first material that forms pellicle membranes 100 (as shown in FIGS. 3A and 3B) for about 10 hours. In some embodiments, the working temperature is in range from about 400° C. to about 700° C., and is in range from about 500° C. to about 600° C. in other embodiments. In some embodiments, the working pressure is in range from about 0.8 atm to about 1.2 atm, and is in range from about 0.9 atm to about 1.1 atm in other embodiments.

In other embodiments, other source materials are used as precursors to deposit wrapping layers of other materials (such as SiC and MoS₂) than BN over the bundles 20 of nanotubes 10 of a first material that forms pellicle membranes 100.

In some embodiments, SiC is formed or grown by CVD, using silane (SiH₄) and light hydrocarbons (C₂H₄ or C₃H₈) as precursors, diluted in a massive flow of hydrogen (H₂), at a growth temperature in a range from about 1500° C. to about 1600° C. and a pressures in a range from about 100 mbar to about 300 mbar.

In some embodiments, MoS₂ is formed or grown by CVD, using MoO₃ or MoCl₅ as Mo precursor, in which solid MoO₃ or MoCl₅ typically in the form of powders are vaporized and converted to MoS₂ by reacting with S vapor at high temperatures (>800° C.). MoO₃ or MoCl₅ are placed at the hottest zone (temperature >800° C.) of a furnace to vaporize them. Sulfur vapor as S precursor is introduced into the furnace by heating sulfur powder and carrying the vapor with Ar flow. These precursors react to produce MoS₂.

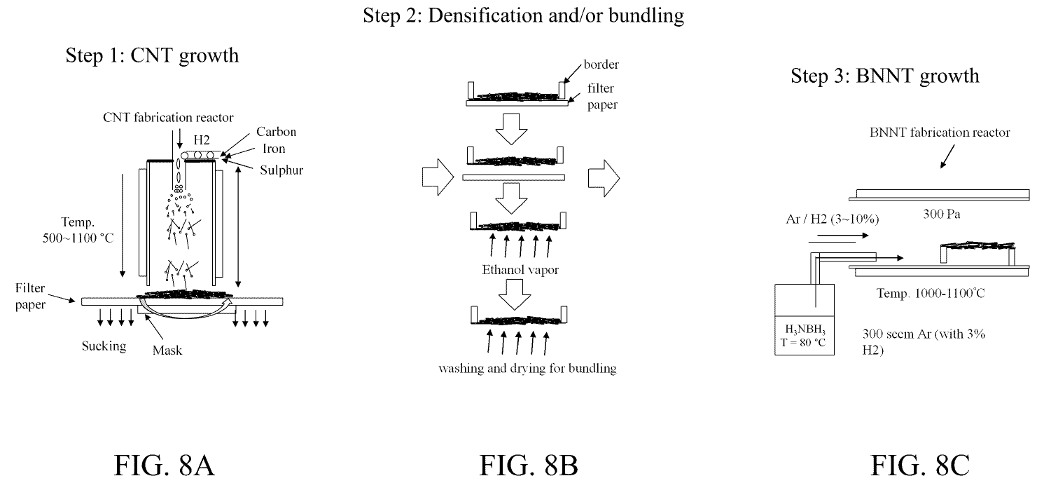

FIGS. 8A, 8B and 8C show sequential operations of manufacturing a pellicle membrane for an EUV reflective mask in accordance with an embodiment of present disclosure.

FIG. 8A shows a CVD operation of forming or growing CNTs according to an embodiment of the present disclosure. In some embodiments, CNTs are formed or grown in a CNT fabrication reactor using carbon or corban containing material as precursor at a working temperature in a range from about 500° C. to about 1100° C. In some embodiments, Fe or Fe containing material is used a catalyst for the CNT growth. In some embodiments, the formed CNTs are filtered with a support membrane, such as a filter paper. In some embodiments, the formed CNTs are sucked by applying a pressure control for uniform CNT dispersion.

FIG. 8B shows the operation of forming CNT bundles. In some embodiments, CNTs along with the filter paper are transferred to another place and are bordered by a border (support frame). After that, the filter paper is detached from the CNTs, and the CNTs are processed with solvent vapor, such as ethanol vapor. Then, CNTs are washed with a higher boiling point solvent (such as isoamyl acetate) and are dried for densification and bundling, thereby forming CNT bundles.

FIG. 8C shows a low pressure thermal CVD operation of forming BNNT layers wrapping the CNT bundles. In some embodiments, H₃NBH₃ is used as B and N precursors to deposit wrapping BN layers over the formed bundles, Ar gas flow (with 3-10% H₂) of a flow rate 300 sccm is used as a carrier gas, and Ar gas is used as a purge gas. In some embodiments, the working temperature is in range from about 900° C. to about 1200° C., and is in range from about 1000° C. to about 1100° C. in other embodiments. In some embodiments, the working pressure is in range from about 280 Pa to about 320 Pa, and is in range from about 290 Pa to about 310 Pa in other embodiments. Due to the high temperature in the process of forming BNNT wrapping layers, Fe or Fe containing catalyst in the CNTs or CNT bundles are reduced or even removed, thereby improving EUV transmittance of the membrane.

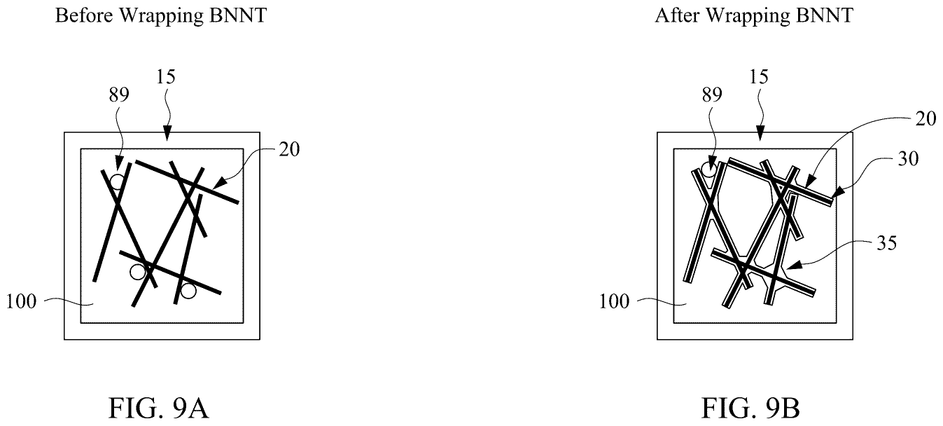

FIGS. 9A and 9B are schematic views illustrating reduction of metal or metal-containing catalyst from bundles of nanotubes in accordance with an embodiment of the present disclosure. FIG. 9A shows a pellicle membrane 100 including bundles 20 of nanotubes before forming the wrapping BNNT layers on the bundles 20. FIG. 9B shows the pellicle membrane 100 after forming the wrapping BNNT layers 30 on the bundles 20.

As set forth above, in some embodiments, during forming the nanotubes (such as nanotubes 10 as shown in FIGS. 3A-3D), a metal or metal-containing catalyst selected from a group consisting of Fe, CoFe, Co, CoNi, Ni, CoMo and FeMo is introduced for growth of the CNT nanotubes. As shown in FIG. 9A, before forming the wrapping BNNT layers on the bundles 20, the membrane 100 (with or without a pellicle frame 15) includes residual metal or metal-containing catalyst particles 89 therein.

As set forth above, in some embodiments, the wrapping BNNT layers are formed on the plurality of nanotube bundles in a furnace (as shown in FIGS. 7A and 7B) at a high temperature (such as in a range from about 1000° C. to about 1200° C.). As shown in FIG. 9B, after forming the wrapping BNNT layers 30 on the CNT bundles 20, the metal or metal-containing catalyst particles 89 are greatly reduced from the nanotube bundles 20 due to the high temperature in the process of forming the wrapping BNNT layers 30, thereby improving transmittance of membrane 100. In some embodiments, as shown in FIG. 9B, thicker wrapping BNNT layers 30 are formed at intersections 35 of the bundles 20 in the membrane 100.

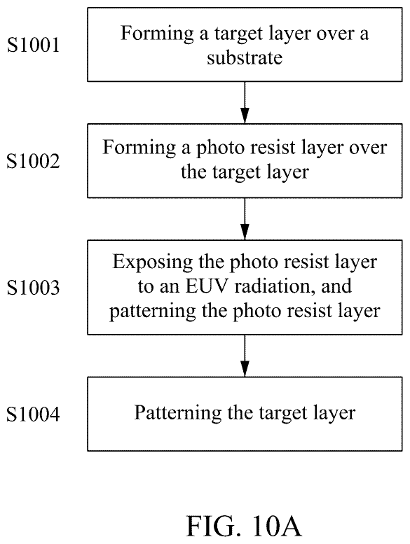

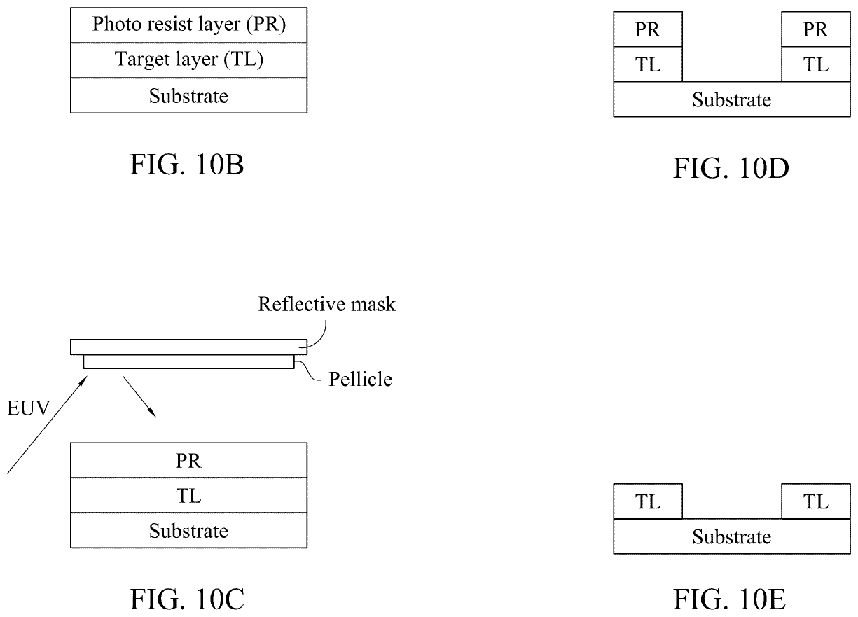

FIG. 10A shows a flowchart of a method of making a semiconductor device, and FIGS. 10B, 10C, 10D and 10E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively, the semiconductor substrate includes germanium, silicon germanium or other suitable semiconductor material, such as a Group III-V semiconductor material.

At S1001 of FIG. 10A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings.

At S1002 of FIG. 10A, a photo resist layer is formed over the target layer, as shown in FIG. 10B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer.

At S1003 of FIG. 10A, the photo resist layer is patterned using an EUV reflective mask with a pellicle as set forth above, as shown in FIG. 10C. The patterning of the photo resist layer includes performing a photolithography exposing process by an EUV exposing system using the EUV mask. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S1004 of FIG. 10A, the target layer is patterned utilizing the patterned photo resist layer as an etching mask, as shown in FIG. 10D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma etching, as shown in FIG. 10E.

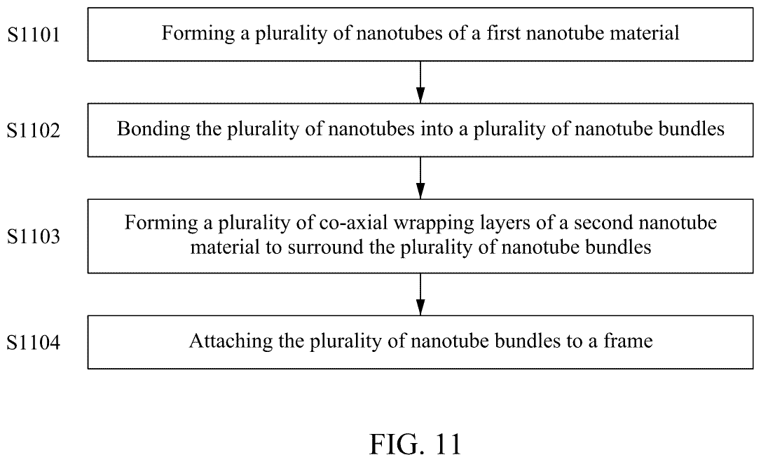

FIG. 11 shows a flowchart of a method of manufacturing a pellicle for an EUV reflective mask in accordance with an embodiment of present disclosure. It is understood that additional operations can be provided before, during, and after the processes shown by FIG. 11, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 1A and 1B, in some embodiments, a pellicle 1000 includes a frame 15 and a membrane 100 attached to the frame 15. As shown in FIGS. 3A and 3B, in some embodiments, the membrane 100 includes a plurality of nanotube bundles 20, each including a plurality of nanotubes 10 of a first material, and a plurality wrapping layers 30 of a second material surrounding the plurality of nanotube bundles 20. In some embodiments, the first and the second nanotube materials are different from each other.

At S1101 of FIG. 11, a plurality of multi-wall nanotubes 10 of a first material are formed (also as shown in FIGS. 3A and 3B). In some embodiments, the first nanotube material is C, and in other embodiments, the first nanotube material is one selected from a group consisting of C, BN, hBN, SiC, MoS₂, MoSe₂, WS₂, WSe₂, SnS₂, SnS, ZrO₂, ZrO and TiO₂. As shown in FIGS. 5A-5C, in some embodiments, nanotubes 10 are formed by a chemical vapor deposition (CVD) process using a furnace (such as a vertical furnace) 500, and a membrane 100 is thus formed. In some embodiments, during forming the nanotubes 10 of a first material, an appropriate catalyst selected from a group consisting of Fe, CoFe, Co, CoNi, Ni, CoMo and FeMo is used that helps the growth of the multi-wall nanotubes 10.

At S1102 of FIG. 11, the plurality of nanotubes 10 are bonded into a plurality of nanotube bundles 20 (as shown in FIGS. 3A and 3B). In some embodiments, a number of the nanotubes in a medium bundle is in a range from 2 to 15; in other embodiments, the number of the nanotubes in a large bundle is in a range from 16 to 100; and in further other embodiments, the number of the nanotubes in a very large bundle is greater than 100. As shown in FIGS. 6A and 6B, in some embodiments, the bundles 20 of single-wall or multiwall nanotubes 10 are formed by using a Joule heating apparatus 600 at a temperature in in range from about 800° C. to about 2000° C. The nanotube bundles 20 of multi-wall nanotubes 10 are not limited to be formed in this way, and can be formed in other ways.

At S1103 of FIG. 11, a plurality of co-axial wrapping layers 30 of a second material different from the first nanotube material are formed to surround each of the plurality of nanotube bundles 20 (as shown in FIGS. 3A and 3B). In some embodiments, the second nanotube material is BN or hBN, and in other embodiments, the second nanotube material is SiC, MoS₂, MoSe₂, WS₂, WSe₂, SnS₂, SnS, ZrO₂, ZrO, or TiO₂. In some embodiments, an amount of any of the first nanotube material and the second nanotube material is greater than 10% of a total amount thereof by weight.

In some embodiments, as shown in FIGS. 7A and 7B, wrapping layers 30 of a second material are deposited over bundles 20 of nanotubes 10 of a first material that forms membranes 100 in a vertical or horizontal furnace 700. In some embodiments, the working temperature is in range from about 500° C. to about 1200° C., and can be adjusted so that metal particles (e.g., iron as residual catalyst) is vaporized under the vacuum and evacuated. In this way, due to the high temperature adopted during the process of forming bundles 20 of nanotubes, the metal or metal-containing catalyst (such as Fe, CoFe, Co, CoNi, Ni, CoMo, and/or FeMo) that is introduced when forming the nanotubes 10 is greatly reduced from the membrane 100, thereby advantageously improving transmittance of the membrane 100.

In some embodiments, as shown in FIG. 3A, during forming a plurality of co-axial wrapping layers 30 of a second material (such as BN) to surround the bundles 20 of nanotubes 10 (such as C) of a first material, given inner diameters D of the nanotubes 10 are equal to or less than 2 nm (D≤2 nm), no second nanotube material fills into inner-most walls of the plurality of multiwall nanotubes 10.

In other embodiments, as shown in FIG. 3B, during forming the co-axial wrapping layers 30 of a second material (such as BN) to surround the bundles 20 of nanotubes 10 (such as C) of a first material, given inner diameters D of the nanotubes 10 are greater than 2 nm (D>2 nm), at least one layer of the second nanotube material fills into inner-most walls of the plurality of multiwall nanotubes 10.

At S1104 of FIG. 11, the wrapped plurality of nanotube bundles 20 are attached to a frame 15, thereby forming the pellicle 1000 (as shown in FIGS. 1A and 1B). In some embodiments, a transmittance of the membrane 100 is in a range from about 50% to about 99%.

In other embodiments, after a membrane with CNT bundles is already formed, the CNT membrane is attached to a border (e.g., made of Si, Qz or other materials), a second nano-tube material is applied to wrap the CNT bundles, a third nano-tube material is applied on the second nano-tube material. After that, the membrane is attached to a frame with vent holes, thereby forming a pellicle. Then, the pellicle is mounted to an EUV photo mask.

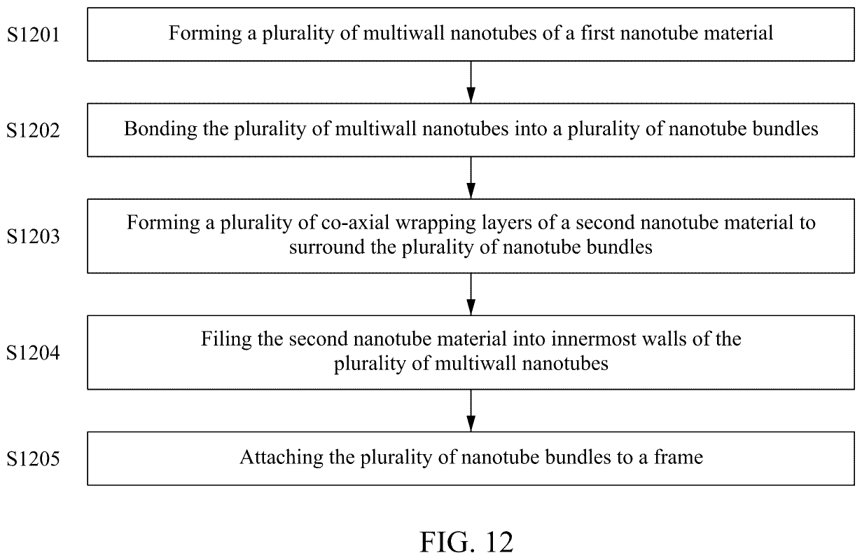

FIG. 12 shows a flowchart of a method of manufacturing a pellicle for an EUV reflective mask in accordance with another embodiment of present disclosure. As shown in FIGS. 1A and 1B, in some embodiments, the pellicle 1000 includes a frame 15 and a membrane 100 attached to the frame 15. As shown in FIGS. 3C and 3D, in some embodiments, the membrane 100 includes a plurality of nanotube bundles 20, each including a plurality of multiwall nanotubes 10 made of a first material and bonded together; a plurality of co-axial first wrapping layers 40 of a second material on the plurality of nanotube bundles 20; and a plurality of co-axial second wrapping layers 30 of a third material on the plurality of co-axial first wrapping layers. In some embodiments, the first, the second, and the third materials are different from each other.

It is understood that additional operations can be provided before, during, and after the processes shown by FIG. 12, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

At S1201 of FIG. 12, a plurality of multi-wall nanotubes 10 of a first nanotube material (such as C) are formed. In some embodiments, the first nanotube material is C, and in other embodiments, the first nanotube material is one selected from a group consisting of C, BN, hBN, SiC, MoS₂, MoSe₂, WS₂, WSe₂, SnS₂, SnS, ZrO₂, ZrO and TiO₂. As shown in FIGS. 5A-5C, in some embodiments, nanotubes 10 are formed by a chemical vapor deposition (CVD) process using a furnace (such as a vertical furnace) 500, and then a membrane 100 is formed and attached onto a frame 15. In some embodiments, during forming the nanotubes 10 of a first material, an appropriate metal or metal-containing catalyst selected Fe, CoFe, Co, CoNi, Ni, CoMo, or FeMo is introduced to help growth of the multi-wall nanotubes 10.

At S1202 of FIG. 12, the plurality of nanotubes 10 into a plurality of nanotube bundles 20, each nanotube bundle 20 including at least two multi-wall nanotubes 10 of the first nanotube material. In some embodiments, a number of the nanotubes in one nanotube bundle is in a range from 2 to 15; in other embodiments, the number of the nanotubes in one nanotube bundle is in a range from 16 to 100; and in further other embodiments, the number of the nanotubes in one nanotube bundle is greater than 100. As shown in FIGS. 6A and 6B, in some embodiments, the nanotube bundles 20 of multi-wall nanotubes 10 are formed by using a Joule heating apparatus 600 at a temperature in in range from about 800° C. to about 2000° C. The nanotube bundles 20 of multi-wall nanotubes 10 are not limited to be formed in this way, and can be formed in other ways.

At S1203 of FIG. 12, a plurality of co-axial first wrapping layers 30 of a second nanotube material (such as SiC) different from the first nanotube material (such as C) are formed to surround each of the plurality of nanotube bundles 20. In some embodiments, the second nanotube material is BN or hBN, and in other embodiments, the second nanotube material is MoS₂, MoSe₂, WS₂, WSe₂, SnS₂, SnS, ZrO₂, ZrO, or TiO₂. In some embodiments, an amount of any of the first nanotube material and the second nanotube material is greater than 10% of a total amount thereof by weight. In some embodiments, the plurality of co-axial first wrapping layers 30 of the second nanotube material are formed on the plurality of nanotube bundles 20 of the membrane 100 in a furnace at a temperature in a range from about 1000° C. to about 1200° C., and thus the metal or metal-containing catalyst is partially or entirely removed from the plurality of nanotube bundles 20 of the membrane 100, thereby improving transmittance of the membrane 100.

At S1204 of FIG. 12, the second nanotube material 30′ fills into inner-most walls of the plurality of multi-wall nanotubes 10 within the plurality of nanotube bundles 20. In some embodiments, as shown in FIG. 3C, during depositing a plurality of co-axial wrapping layers 30 of a second material to surround the bundles 20 of nanotubes 10 of a first material, when inner diameters D of the nanotubes 10 are equal to or less than 2 nm (D≤2 nm), no second nanotube material fills into inner-most walls of the plurality of nanotubes 10. In other embodiments, as shown in FIG. 3D, during depositing a plurality of co-axial wrapping layers 30 of a second material to surround the bundles 20 of nanotubes 10 of a first material, when inner diameters D of the nanotubes 10 are greater than 2 nm (D>2 nm), one or more layers 30′ of the second nanotube material fills into inner-most walls of the plurality of nanotubes 10.

Furthermore, as shown in FIGS. 3C and 3D, in some embodiments, a plurality of co-axial second wrapping layers 40 of a third nanotube material (e.g., BN) are formed to surround the plurality first wrapping layers 30 of the second nanotube material (such as SiC) by changing one or more source gases in S1203/S1204. In some embodiments, as shown in FIGS. 3C and 3D, the first material is C; the second material is selected from a group consisting of SiC, MoS₂, MoSe₂, WS₂, WSe₂, SnS₂, SnS, ZrO₂, ZrO and TiO₂; and the third material is selected from a group consisting of BN and hBN. In some embodiments, an amount of any of the first material, the second material and the third material is greater than 10% of a total amount thereof by weight.

In some embodiments, as shown in FIG. 3C, during a plurality of co-axial wrapping layers 30 of a second material (such as SiC) are deposited to surround the bundles 20 of nanotubes 10 of a first material (such as C), when inner diameters D of the nanotubes 10 are equal to or less than 2 nm (D≤2 nm), no second or third nanotube material fills into inner-most walls of the plurality of nanotubes 10.

In other embodiments, as shown in FIG. 3D, during a plurality of co-axial wrapping layers 30 of a second material (such as SiC) are deposited to surround the bundles 20 of nanotubes 10 (such as C) of a first material, when inner diameters D of the nanotubes 10 are greater than 2 nm (D>2 nm), at least one layer 30′ of the second nanotube material fills into innermost walls of the plurality of nanotubes 10. Furthermore, during a plurality of co-axial wrapping layers 40 of a third material (such as BN) are deposited to surround the plurality of co-axial wrapping layers 30 of a second material (such as SiC), when inner diameters D′ of the nanotubes 10 are greater than 2 nm (D′>2 nm), at least one layer 40′ of the third nanotube material fills into inner-most walls of the plurality of nanotubes 10. In this way, mechanical strength of the membrane 100 is enhanced, thereby improving lifetime of the membrane 100.

At S1205 of FIG. 12, the wrapped plurality of nanotube bundles 20 are attached to a frame 15, thereby forming the pellicle 1000 (as shown in FIGS. 1A and 1B). 30. In some embodiments, a transmittance of the membrane 100 is in a range from about 60% to about 90%.

A pellicle for an EUV reflective mask includes a membrane attached to a frame according to embodiments of the present disclosure. In some embodiments, the membrane includes a plurality of nanotube bundles, each including a plurality of multi-wall nanotubes 10 made of a first nanotube material and bonded together, and a plurality wrapping layers of a second nanotube material on the plurality of nanotube bundles, the second nanotube material being different from the first nanotube material. The pellicle advantageously has good EUV light transmittance, increased strength under EUV exposure environment, and thereby having improved quality and prolonged lifetime.

It will be understood that not all advantages have been necessarily discussed herein, no particular advantage is required for all embodiments or examples, and other embodiments or examples may offer different advantages.

In accordance with one aspect of the present disclosure, a method of manufacturing a pellicle for an extreme ultraviolet (EUV) reflective mask includes: forming a plurality of multi-wall nanotubes of a first nanotube material; bonding the plurality of nanotubes into a plurality of nanotube bundles; forming a plurality of co-axial wrapping layers of a second nanotube material different from the first nanotube material to surround each of the plurality of nanotube bundles; and attaching the wrapped plurality of nanotube bundles to a pellicle frame. In one or more of the foregoing and following embodiments, where inner diameters of the plurality of nanotubes are greater than 2 nm, at least one nanotube layer of the second nanotube material is filled into inner-most walls of the plurality of nanotubes within the plurality of nanotube bundles. In one or more of the foregoing and following embodiments, the first nanotube material includes a carbon based material, and the second nanotube material is selected from a group consisting of BN, hBN, SiC, MoS₂, MoSe₂, WS₂, WSe₂, SnS₂, SnS, ZrO₂, ZrO and TiO₂. In one or more of the foregoing and following embodiments, an amount of any of the first nanotube material and the second nanotube material is greater than 10% of a total amount thereof by weight. In one or more of the foregoing and following embodiments, an amount of any of the first nanotube material and the second nanotube material is greater than 10% of a total amount thereof by weight. In one or more of the foregoing and following embodiments, wherein a number of the nanotubes in one nanotube bundle is in a range from 2 to 15. In one or more of the foregoing and following embodiments, wherein a number of the nanotubes in one nanotube bundle is in a range from 16 to 100. In one or more of the foregoing and following embodiments, wherein a number of the nanotubes in one nanotube bundle is greater than 100.

In accordance with another aspect of the present disclosure, a method of manufacturing a pellicle for an extreme ultraviolet (EUV) reflective mask includes: forming a plurality of multi-wall nanotubes of a first nanotube material; bonding the plurality of nanotubes into a plurality of nanotube bundles, each nanotube bundle including at least two multi-wall nanotubes of the first nanotube material; forming a plurality of co-axial first wrapping layers (30) of a second nanotube material different from the first nanotube material to surround each of the plurality of nanotube bundles; filling the second nanotube material into inner-most walls of the plurality of multi-wall nanotubes within the plurality of nanotube bundles; and attaching the wrapped plurality of nanotube bundles to a pellicle frame. In one or more of the foregoing and following embodiments, the first nanotube material comprises a carbon based material, and wherein the second nanotube material comprises a boron-nitride based material. In one or more of the foregoing and following embodiments, the first nanotube material and the second nanotube material are selected from a group consisting of C, BN, hBN, SiC, MoS₂, MoSe₂, WS₂, WSe₂, SnS₂, SnS, ZrO₂, ZrO and TiO₂. In one or more of the foregoing and following embodiments, during forming the plurality of nanotubes of the first nanotube material, a metal or metal-containing catalyst selected from a group consisting of Fe, CoFe, Co, CoNi, Ni, CoMo and FeMo is introduced for growth of the plurality of nanotubes. In one or more of the foregoing and following embodiments, the plurality of co-axial first wrapping layers of the second nanotube material are formed on the plurality of nanotube bundles in a furnace at a temperature in a range from about 1000° C. to about 1200° C., and the metal or metal-containing catalyst is partially removed from the plurality of nanotube bundles. In one or more of the foregoing and following embodiments, the method further includes forming a plurality of co-axial second wrapping layers of a third nanotube material (e.g., SiC) on the plurality first wrapping layers of the second nanotube material. In one or more of the foregoing and following embodiments, the third nanotube material is different from the first and the second nanotube materials and is selected from a group consisting of C, BN, hBN, SiC, MoS₂, MoSe₂, WS₂, WSe₂, SnS₂, SnS, ZrO₂, ZrO and TiO₂. In one or more of the foregoing and following embodiments, an amount of any of the first, the second, and the third nanotube materials is greater than 10% of a total amount thereof by weight.

In accordance with another aspect of the present disclosure, a pellicle for an extreme ultraviolet (EUV) reflective mask includes: a frame; and a membrane attached to the frame, wherein the membrane includes: a plurality of nanotube bundles, each including a plurality of multi-wall nanotubes made of a first nanotube material and bonded together; and a plurality of co-axial first wrapping layers of a second nanotube material different from the first nanotube material on the plurality of nanotube bundles. In one or more of the foregoing and following embodiments, where inner diameters of the plurality of multi-wall nanotubes are greater than 2 nm, one of the plurality of nanotubes includes at least one layer of the second nanotube material within inner-most walls thereof. In one or more of the foregoing and following embodiments, the first nanotube material includes a carbon based material, and the second nanotube material is selected from a group consisting of BN, hBN, SiC, MoS₂, MoSe₂, WS₂, WSe₂, SnS₂, SnS, ZrO₂, ZrO and TiO₂. In one or more of the foregoing and following embodiments, the pellicle further includes a plurality of co-axial second wrapping layers of a third nanotube material co-axially wrapping the plurality co-axial first wrapping layers of the second nanotube material, wherein the third nanotube material is different from the first and the second nanotube materials and is selected from a group consisting of C, BN, hBN, SiC, MoS₂, MoSe₂, WS₂, WSe₂, SnS₂, SnS, ZrO₂, ZrO and TiO₂. In one or more of the foregoing and following embodiments, a transmittance of the membrane is in a range from about 50% to about 99%.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a pellicle for an extreme ultraviolet (EUV) reflective mask, comprising:
forming a plurality of multi-wall nanotubes of a first nanotube material;
bonding the plurality of nanotubes into a plurality of nanotube bundles;
forming a plurality of co-axial wrapping layers of a second nanotube material different from the first nanotube material to surround each of the plurality of nanotube bundles; and
attaching the wrapped plurality of nanotube bundles to a pellicle frame.

2. The method of claim 1, further comprising where inner diameters of the plurality of nanotubes are greater than 2 nm, filling at least one nanotube layer of the second nanotube material into inner-most walls of the plurality of nanotubes within the plurality of nanotube bundles.

3. The method of claim 1, wherein the first nanotube material comprises a carbon based material, and wherein the second nanotube material is selected from a group consisting of BN, hBN, SiC, MoS₂, MoSe₂, WS₂, WSe₂, SnS₂, SnS, ZrO₂, ZrO and TiO₂.

4. The method of claim 1, wherein an amount of any of the first nanotube material and the second nanotube material is greater than 10% of a total amount thereof by weight.

5. The method of claim 1, wherein a number of the nanotubes in one nanotube bundle is in a range from 2 to 15.

6. The method of claim 1, wherein a number of the nanotubes in one nanotube bundle is in a range from 16 to 100.

7. The method of claim 1, wherein a number of the nanotubes in one nanotube bundle is greater than 100.

8. A method of manufacturing a pellicle for an extreme ultraviolet (EUV) reflective mask, comprising:
forming a plurality of multi-wall nanotubes of a first nanotube material;
bonding the plurality of nanotubes into a plurality of nanotube bundles, each nanotube bundle among the plurality of nanotube bundles including at least two multi-wall nanotubes of the first nanotube material;
forming a plurality of co-axial first wrapping layers of a second nanotube material different from the first nanotube material to surround each of the plurality of nanotube bundles;
filling the second nanotube material into inner-most walls of the plurality of multi-wall nanotubes within the plurality of nanotube bundles; and
attaching the wrapped plurality of nanotube bundles to a pellicle frame.

9. The method of claim 8, wherein the first nanotube material comprises a carbon based material, and wherein the second nanotube material comprises a boron-nitride based material.

10. The method of claim 8, wherein the first nanotube material and the second nanotube material are selected from a group consisting of C, BN, hBN, SiC, MoS₂, MoSe₂, WS₂, WSe₂, SnS₂, SnS, ZrO₂, ZrO and TiO₂.

11. The method of claim 8, wherein during forming the plurality of nanotubes of the first nanotube material, a metal or metal-containing catalyst selected from a group consisting of Fe, CoFe, Co, CoNi, Ni, CoMo and FeMo is introduced for growth of the plurality of nanotubes.

12. The method of claim 11, wherein the plurality of co-axial first wrapping layers of the second nanotube material are formed on the plurality of nanotube bundles in a furnace at a temperature in a range from about 1000° C. to about 1200° C., and wherein the metal or metal-containing catalyst is partially removed from the plurality of nanotube bundles.

13. The method of claim 8, further comprising forming a plurality of co-axial second wrapping layers of a third nanotube material on the plurality first wrapping layers of the second nanotube material.

14. The method of claim 13, wherein the third nanotube material is BN or hBN.

15. The method of claim 13, wherein an amount of any of the first, the second, and the third nanotube materials is greater than 10% of a total amount thereof by weight.

16. A pellicle for an extreme ultraviolet (EUV) reflective mask, comprising:
a frame; and
a membrane attached to the frame,
wherein the membrane comprises:
a plurality of nanotube bundles, each including a plurality of multi-wall nanotubes made of a first nanotube material and bonded together; and
a plurality of co-axial first wrapping layers of a second nanotube material different from the first nanotube material to surround the plurality of nanotube bundles.

17. The pellicle of claim 16, wherein where inner diameters of the plurality of multi-wall nanotubes are greater than 2 nm, one of the plurality of nanotubes includes at least one layer of the second nanotube material within inner-most walls thereof.

18. The pellicle of claim 16, wherein the first nanotube material comprises a carbon based material, and wherein the second nanotube material is selected from a group consisting of BN, hBN, SiC, MoS₂, MoSe₂, WS₂, WSe₂, SnS₂, SnS, ZrO₂, ZrO and TiO₂.

19. The pellicle of claim 16, further comprising a plurality of co-axial second wrapping layers of a third nanotube material co-axially wrapping the plurality co-axial first wrapping layers of the second nanotube material, wherein the third nanotube material is different from the first and the second nanotube materials and is selected from a group consisting of C, BN, hBN, SiC, MoS₂, MoSe₂, WS₂, WSe₂, SnS₂, SnS, ZrO₂, ZrO and TiO₂.

20. The pellicle of claim 16, wherein a transmittance of the membrane is in a range from about 50% to about 99%, and wherein the plurality of nanotube bundles are dispersed in a specific orientation or randomly dispersed.
